(19) United States
(12) Patent Application Publication
(10) Pub. No.: US 2019/0068162 A1
(43) Pub. Date: Feb. 28, 2019

(54) CRYSTAL CONTROLLED OSCILLATOR

(71) Applicant: NIHON DEMPA KOGYO CO., LTD., Tokyo (JP)

(72) Inventor: Takashi MATSUMOTO, Saitama (JP)

(73) Assignee: NIHON DEMPA KOGYO CO., LTD., Tokyo (JP)

(21) Appl. No.: 16/109,682

(22) Filed: Aug. 22, 2018

(30) Foreign Application Priority Data
Aug. 23, 2017 (JP) 2017-160519

(51) Int. Cl. H03H 9/17; H01L 27/02

(52) U.S. Cl. CPC H03H 9/172; H03H 9/176; H01L 27/0203

(57) ABSTRACT

A crystal controlled oscillator is provided and includes a ceramic package, a plurality of metal patterns on the substrate, an IC chip, and an alumina coating portion. The ceramic package includes a substrate therein. The metal pattern includes a pad region and a wiring region. The IC chip oscillates a crystal resonator. The alumina coating portion covers the pad regions of the plurality of metal patterns. The alumina coating portion includes openings for mounting solders corresponding to the pad regions. The opening of the alumina coating portion is formed in a shape having a size to be placed within the pad region, even if a print displacement of the metal pattern occurs.

### CROSS-REFERENCE TO RELATED APPLICATIONS

This application is based on and claims priority under 35 U.S.C. § 119 to Japanese Patent Application No. 2017-160519, filed on Aug. 23, 2017, the entire content of which is incorporated herein by reference.

### TECHNICAL FIELD

This disclosure relates to a crystal controlled oscillator, especially relates to a crystal controlled oscillator configured to form solder bumps in a uniform height on a substrate of a ceramic package.

### DESCRIPTION OF THE RELATED ART

[Conventional Technique]

There is provided a conventional crystal controlled oscillator in which a metal pattern disposed on a ceramic package is joined to an electronic component using a solder. The electronic component is an IC chip that includes an oscillator circuit.

In this case, there is a problem that the solder flows out to a wiring pattern and the like other than a position to be joined and an amount of the solder decreases, then joining strength is degraded.

Therefore, the following countermeasures are performed.

[Conventional Alumina Coating: FIG. 5]

A conventional alumina coating will be described by referring to FIG. 5. FIG. 5 is an explanatory plan view describing the conventional alumina coating.

As illustrated in FIG. 5, a conventional crystal controlled oscillator has a ceramic package in which metal patterns 12 to become electrodes and the like, patterns 13 for monitor terminals, and alumina coating portions 14 as solder flow prevention regions are formed on a substrate 11.

The alumina coating portion 14 is formed such that an aluminum oxide film is formed so as to cover a part of the metal pattern 12, and the metal pattern 12 is separated into a pad region pattern 12a and a wiring region pattern 12b.

Then, the formed alumina coating portion 14 prevents a solder formed on an IC chip side from flowing out to the wiring region pattern 12b.

[Conventional Laser Trimming: FIG. 6]

Next, a conventional laser trimming will be described by referring to FIG. 6. FIG. 6 is an explanatory plan view describing the conventional laser trimming.

As illustrated in FIG. 6, a conventional crystal controlled oscillator has a ceramic package in which metal patterns 22 to become electrodes and the like, patterns 23 for monitor terminals, and laser trimming portions 24 as solder flow prevention regions are formed on a substrate 21.

The laser trimming portion 24 is formed such that a part of the metal pattern 22 is removed with a laser to form a groove, and the metal pattern 22 is separated into a pad region pattern 22a on which a solder is formed and a wiring region pattern 22b.

Then, the formed laser trimming portion 24 prevents the solder from flowing out to the wiring region pattern 22b, even if the solder is applied over the pad region pattern 22a.

### RELATED ART

As related prior arts, Japanese Patent No. 5828480 has disclosed “PIEZOELECTRIC DEVICE”, and Japanese Unexamined Patent Application Publication No. 2011-234203 has disclosed “METHOD OF MANUFACTURING PIEZOELECTRIC OSCILLATOR.”

Japanese Patent No. 5828480 describes a configuration for preventing a solder from flowing out with an alumina coating.

Japanese Unexamined Patent Application Publication No. 2011-234203 describes a configuration for preventing a solder from flowing out with a laser trimming.

However, the conventional crystal controlled oscillator has a problem that downsizing of a product decreases an area on which the alumina coating is performed, occurrence of print displacement of the metal pattern causes a product in which the alumina coating fails to cover the entire metal pattern to be mixed, and consequently, the solder flows out to the wiring pattern to cause solder bumps to have uneven heights.

The conventional crystal controlled oscillator has a problem that downsizing of a product decreases a length of a groove formed by the laser trimming, occurrence of print displacement of the metal pattern causes a product in which the groove formed by the laser trimming does not completely cross the metal pattern to be mixed, and consequently, the solder flows out to the wiring pattern to cause solder bumps to have uneven heights.

The conventional alumina coating and laser trimming cause dispersion in area of a solder implementing pattern due to process accuracy in some cases.

Especially, when an IC chip that includes solder bumps with multi-terminals is implemented, dispersion in implementing area on a package side causes dispersion in height of the bumps to incline a component in some cases. This causes a portion on which resin filling of an underfill and the like can be performed after the implementing and a portion on which the resin filling cannot be performed, which influences the resin filling in some cases.

A need thus exists for a crystal controlled oscillator which is not susceptible to the drawback mentioned above.

### SUMMARY

According to an aspect of this disclosure, there is provided a crystal controlled oscillator that includes a ceramic package, a plurality of metal patterns on the substrate, an IC chip, and an alumina coating portion. The ceramic package includes a substrate therein. The metal pattern includes a pad region and a wiring region. The IC chip oscillates a crystal resonator. The alumina coating portion covers the pad regions of the plurality of metal patterns. The alumina coating portion includes openings for mounting solders corresponding to the pad regions. The opening of the alumina coating portion is formed in a shape having a size to be placed within the pad region, even if a print displacement of the metal pattern occurs.

### BRIEF DESCRIPTION OF THE DRAWINGS

The foregoing and additional features and characteristics of this disclosure will become more apparent from the following detailed description considered with reference to the accompanying drawings.

FIG. 1 is an explanatory plan view illustrating a metal pattern on a substrate of this crystal controlled oscillator.

FIG. 2 is an explanatory plan view describing an alumina coating of this crystal controlled oscillator.

FIG. 3 is an explanatory plan view when the alumina coating of this crystal controlled oscillator is displaced.

FIG. 4 is an explanatory plan view describing an alumina coating of a second crystal controlled oscillator.

FIG. 5 is an explanatory plan view describing a conventional alumina coating.

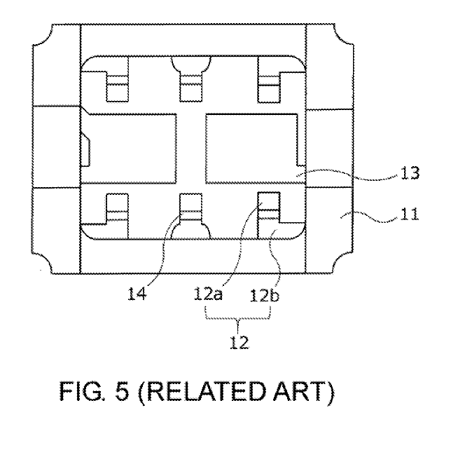

FIG. 6 is an explanatory plan view describing a conventional laser trimming.

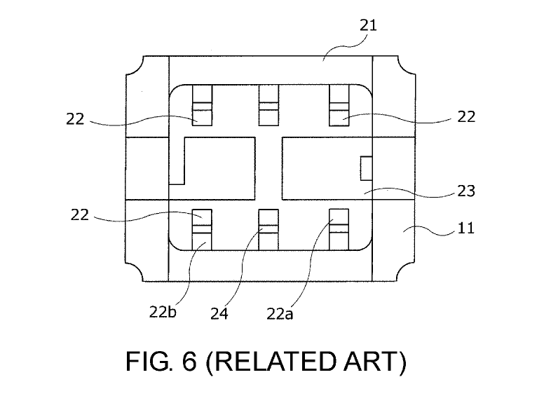

### DETAILED DESCRIPTION

The following describes an embodiment of the disclosure with reference to the drawings.

### Outline of Embodiment

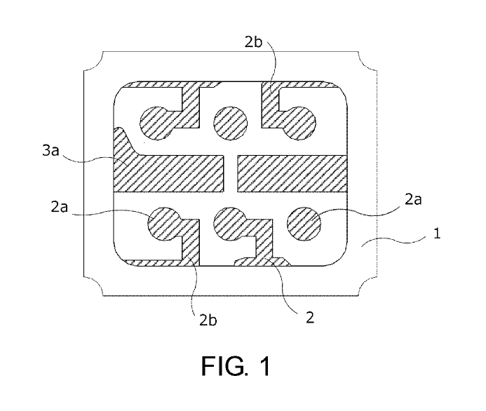

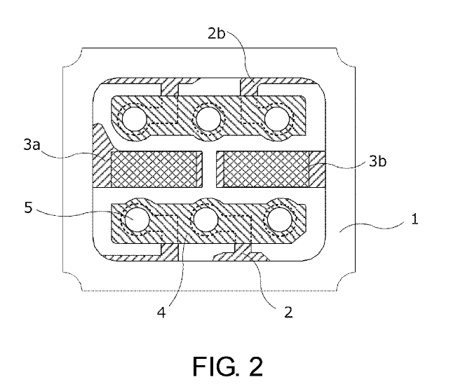

A crystal controlled oscillator according to an embodiment of the disclosure includes a strip-shaped alumina coating portion and an opening. The alumina coating portion is formed to cover a pad region of a metal pattern formed on a substrate in a ceramic package. The opening is disposed for mounting a solder on the pad region. The opening has a size configured to be placed within the pad region even if print displacement of the metal pattern or the alumina coating portion occurs. Then, since the solder is mounted on the opening even if the print displacement of the metal pattern or the alumina coating portion occurs, the solder does not flow out to a wiring region and a size of the pad region exposed from the opening does not change, thus maintaining solder bumps in a uniform height.

[This Crystal Controlled Oscillator: FIG. 1 and FIG. 2]

The crystal controlled oscillator according to the embodiment of the disclosure (this crystal controlled oscillator/a first crystal controlled oscillator) will be described by referring to FIG. 1 and FIG. 2. FIG. 1 is an explanatory plan view illustrating the metal pattern on the substrate of this crystal controlled oscillator. FIG. 2 is an explanatory plan view describing the alumina coating of this crystal controlled oscillator.

[Substrate 1 of this Crystal Controlled Oscillator: FIG. 1]

As illustrated in FIG. 1, this crystal controlled oscillator includes metal patterns 2 as circuit patterns formed on a substrate 1 of a ceramic package.

The metal patterns 2 are used for electrodes and the like, and made of, for example, tungsten and/or molybdenum.

In FIG. 1, the metal patterns 2 include six circular-shaped pad region patterns 2a, and wiring region patterns 2b connected to the pad region patterns 2a.

The pad region patterns 2a formed of the circular-shaped portion alone are electrically connected to a back side surface via through-holes.

Two patterns 3a for characteristic inspection terminals (which is also simply referred to as “measurement terminals”) of a crystal resonator are formed on the center of the substrate 1 in a lateral direction. The characteristic inspection terminal is a terminal for inspecting the characteristic of the crystal resonator, after the crystal resonator is mounted in a package in a manufacturing process of the crystal controlled oscillator.

[Alumina Coating of this Crystal Controlled Oscillator: FIG. 2]

As illustrated in FIG. 2, alumina coating portions 4 as aluminum oxide films are formed on a planar surface in FIG. 1. That is, FIG. 2 illustrates a configuration where the alumina coating portions 4 are laminated on the planar surface in FIG. 1.

FIG. 2 illustrates openings 5 by outlines for easy seeing, while the circular-shaped pad region patterns 2a of the metal patterns 2 are actually seen.

Two alumina coating portions 4 are formed in strip shapes on an upper side and a lower side of the patterns 3a for measurement terminals so as to cover the metal pattern 2. The alumina coating portions 4 include the openings 5 on positions corresponds to the circular-shaped pad region patterns 2a of the metal patterns 2.

While the opening 5 is formed in the circular shape, the opening 5 may be formed in an elliptical shape, a quadrangular shape, or a polygonal shape.

The opening 5 is formed in the circular shape smaller than a circle of the circular-shaped pad region pattern 2a.

The opening 5 has a size to be placed within the pad region pattern 2a, even if print displacement of the metal pattern 2 occurs.

A raised pattern 3b made of a metal film is formed on the pattern 3a for the measurement terminal. The measurement terminal is connected to this raised pattern 3b to measure a frequency and the like.

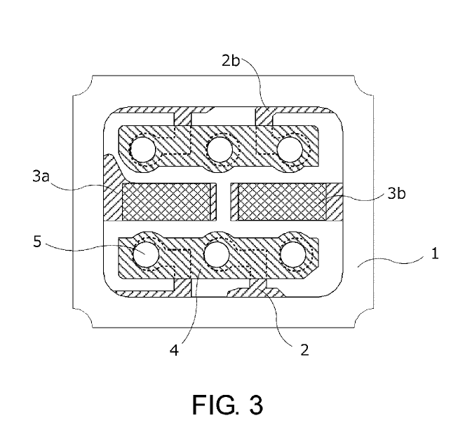

This crystal controlled oscillator includes the opening 5 of the alumina coating portion 4 configured to be placed within the circular-shaped pad region pattern 2a of the metal pattern 2, even if the print displacement of the metal pattern 2 occurs on the substrate 1. This prevents the solder from flowing out to the wiring region pattern 2b due to heating in the opening 5, thus ensuring the solder bumps to be formed in the uniform height.

[Displacement of Alumina Coating Portion: FIG. 3]

While it has been described the case where the print displacement of the metal pattern 2 occurs on the substrate 1 by referring to FIG. 1 and FIG. 2, it is assumed that a print displacement of the alumina coating portion 4 occurs as well. Therefore, the print displacement of the alumina coating portion 4 will be described by referring to FIG. 3. FIG. 3 is an explanatory plan view when the alumina coating portion 4 of this crystal controlled oscillator is displaced to left.

As illustrated in FIG. 3, the opening 5 is configured to be placed within the circular-shaped pad region pattern 2a of the metal pattern 2, even if the print displacement of the alumina coating portion 4 occurs with respect to the metal pattern 2. This ensures the solder bumps to be formed in the uniform height, while preventing the solder from flowing out to the wiring region pattern 2b.

The opening 5 is formed to have the shape and the dimensions such that a range of the assumed print displacement is sufficiently permitted.

The opening 5 is configured to be placed within the pad region pattern 2a, even if the print displacements of both the metal pattern 2 and the alumina coating portion 4 occur.

The opening 5 is configured such that a relational expression a+w<b is satisfied when both the opening 5 and the pad region pattern 2a of the metal pattern 2 have circular shapes, and it is defined that a radius of the opening 5 is a, a radius of the pad region pattern 2a is b, and the print displacement is w.

[Method for Manufacturing this Crystal Controlled Oscillator]

In this crystal controlled oscillator, necessary through-holes are preliminarily formed on the substrate 1 of the ceramic package.

Then, the metal patterns 2 as the circuit patterns and the patterns 3a for the measurement terminals are formed of tungsten and the like on the substrate 1 by printing.

Next, the alumina coating portions 4 that include the openings 5 on the metal patterns 2 are formed by printing and the like.

Then, the raised patterns 3b are formed on the patterns 3a for the measurement terminals.

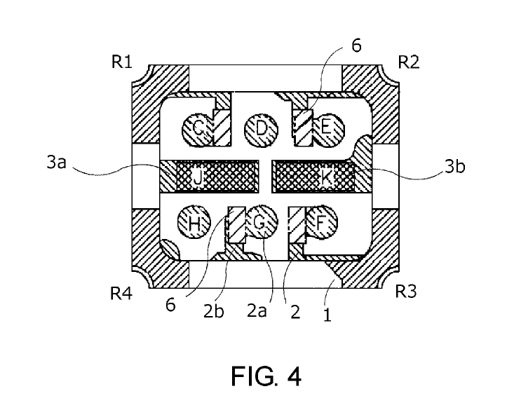

Furthermore, an IC chip (not illustrated) that oscillates the crystal resonator is mounted and the soldering is performed. The solder is formed on an IC chip side, and the solder contacts the opening 5 to be heated when the IC chip is mounted at implementing, thus the soldering is performed. The IC chip includes an oscillator circuit.

[Other Crystal Controlled Oscillator: FIG. 4]

Next, another crystal controlled oscillator (the other crystal controlled oscillator/a second crystal controlled oscillator) according to the embodiment of the disclosure will be described by referring to FIG. 4. FIG. 4 is an explanatory plan view describing an alumina coating of the second crystal controlled oscillator.

The second crystal controlled oscillator (the other crystal controlled oscillator) is configured such that metal patterns on a back side surface are electrically connected to metal patterns on a front side surface via through-holes.

Corner terminals R1 to R4 are formed to have metal films on side surfaces, and serve as through-holes.

As illustrated in FIG. 4, metal patterns 2 and patterns 3a for the measurement terminals are formed on the surface of a substrate 1, and alumina coating portions 6 are formed between the circular-shaped pad region patterns 2a and the wiring region patterns 2b of the metal patterns 2.

Metal films of the raised patterns 3b are formed on the patterns 3a for the measurement terminal.

The alumina coating portion 6 disposed between the pad region pattern 2a and the wiring region pattern 2b of the metal pattern 2 causes the solder to stay within the pad region pattern 2a at implementing without flowing out to the wiring region pattern 2b side, thus ensuring the solder bumps in the uniform height.

### Effect of Embodiment

According to this crystal controlled oscillator (the first crystal controlled oscillator), the opening 5 of the alumina coating portion 4 is configured to be placed within the circular-shaped pad region pattern 2a of the metal pattern 2, even if the print displacement of the metal pattern 2 or the alumina coating portion 4 occurs on the substrate 1. This causes the solder to stay in the opening 5 at implementing without flowing out to any part including the wiring region pattern 2b, thus ensuring the solder bumps to be formed in the uniform height.

According to the other crystal controlled oscillator (the second crystal controlled oscillator), the alumina coating portion 6 formed between the circular-shaped pad region pattern 2a and the wiring region pattern 2b of the metal pattern 2 separates the pad region pattern 2a from the wiring region pattern 2b. This causes the solder to stay in the pad region pattern 2a at implementing without flowing out to the wiring region pattern 2b, thus ensuring the solder bumps to be formed in the uniform height.

The disclosure is appropriate for a crystal controlled oscillator that ensures forming solder bumps in a uniform height to reduce dispersion in quality.

According to the disclosure, the crystal controlled oscillator includes a plurality of metal patterns on a substrate in a ceramic package. The plurality of metal patterns are constituted of pad regions and wiring regions. The crystal controlled oscillator includes an IC chip that oscillates a crystal resonator. The crystal controlled oscillator includes an alumina coating portion that covers the pad regions of the plurality of metal patterns. The alumina coating portion includes openings for mounting solders corresponding to the pad regions. The opening of the alumina coating portion is formed in a shape having a size to be placed within the pad region, even if the alumina coating portion is formed with a print displacement.

According to the disclosure, in the above-described crystal controlled oscillator, the alumina coating portion is formed in a strip shape so as to cover the pad regions of the plurality of metal patterns.

According to the disclosure, in the above-described crystal controlled oscillator, the opening is formed in a circular shape.

According to the disclosure, in the above-described crystal controlled oscillator, the alumina coating portion is formed on a part excluding measurement terminals formed on a ceramic substrate.

According to the disclosure, the crystal controlled oscillator includes the alumina coating portion that covers the pad regions of the plurality of metal patterns, the alumina coating portion includes openings for mounting solders corresponding to the pad regions, and the openings of the alumina coating portion are formed in shapes having sizes to be placed within the pad regions, even if the metal patterns are formed with print displacements. This causes the entire surface exposed from the opening to serve as a pad region to which the IC chip including the solder bumps is mounted even if the print displacements of the metal patterns occur. Then, the solder does not flow out to the wiring region, and further, the size of the opening does not change, thus ensuring the solder bumps in the uniform height.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A crystal controlled oscillator, comprising:
a ceramic package that includes a substrate therein;
a plurality of metal patterns on the substrate, the metal pattern including a pad region and a wiring region;
an IC chip that oscillates a crystal resonator; and
an alumina coating portion that covers the pad regions of the plurality of metal patterns, the alumina coating portion including openings for mounting solders corresponding to the pad regions,
wherein the opening of the alumina coating portion is formed in a shape having a size to be placed within the pad region, even if a print displacement of the metal pattern occurs.

2. The crystal controlled oscillator according to claim 1, wherein
the alumina coating portion is formed in a strip shape configured to cover the pad regions of the plurality of metal patterns.

3. The crystal controlled oscillator according to claim 1, wherein
the opening is formed in a circular shape.

4. The crystal controlled oscillator according to claim 1, wherein
the alumina coating portion is formed on a part excluding a measurement terminal formed on a ceramic substrate.

5. A crystal controlled oscillator, comprising:
a ceramic package that includes a substrate therein;
a plurality of metal patterns on the substrate, the metal pattern including a pad region and a wiring region;
an IC chip that oscillates a crystal resonator; and
an alumina coating portion that covers the pad regions of the plurality of metal patterns, the alumina coating portion including openings for mounting solders corresponding to the pad regions,
wherein the opening of the alumina coating portion is formed in a shape having a size to be placed within the pad region, even if the alumina coating portion is formed with a print displacement.

6. The crystal controlled oscillator according to claim 5, wherein
the alumina coating portion is formed in a strip shape configured to cover the pad regions of the plurality of metal patterns.

7. The crystal controlled oscillator according to claim 5, wherein
the opening is formed in a circular shape.

8. The crystal controlled oscillator according to claim 5, wherein
the alumina coating portion is formed on a part excluding a measurement terminal formed on a ceramic substrate.
